(19) United States
(12) Patent Application Publication
(10) Pub. No.: US 2005/0105267 A1
(43) Pub. Date: May 19, 2005

(54) Heat dispersing device of chassis

(75) Inventor: Shih-Tien Cheng, Taipei (TW)

Correspondence Address: BRUCE H. TROXELL;SUITE 1404, 5205 LEESBURG PIKE, FALLS CHURCH, VA, 22041, US

(73) Assignee: Shuttle Inc.

(21) Appl. No.: 10/833,078

(22) Filed: Apr. 28, 2004

(30) Foreign Application Priority Data
Nov. 19, 2003 (TW) 092220474

(51) Int. Cl. H05K 7/20

(52) U.S. Cl. 361/690

(57) ABSTRACT

The present invention discloses a heat dispersing device of a chassis, comprising a bottom hole at the chassis of a casing and a board hole disposed at a position corresponding to a circuit board inside the casing, wherein the bottom hole and board hole are disposed at an end away from a ventilation hole such that the cool air can have a better traveling path for lowering the temperature of a heat producing component.

### FIELD OF THE INVENTION

The present invention relates to a heat dispersing device of a chassis, more particularly to a chassis of a casing comprising a hole at the bottom of the chassis and a hole on a circuit board inside the casing, such that cool air enters from the hole at the bottom of the chassis and passes through the hole on the circuit board to carry away the heat produced by the heat producing components on the circuit board.

### BACKGROUND OF THE INVENTION

In general, an electronic or electric device usually has a casing and many electronic components inside the casing. These electronic components are mounted onto a circuit board, including but not limited to those for portable computers and desktop computers. Most related electric products also adopt such assembling method.

For electronic components, some generate heat; in other words, electronic components including CPU are heat sources by themselves. The heat must be dispersed effectively to avoid its being accumulated or filled in the casing, which will damage the electronic components inside the casing. For components of high power or fast operation, more heat will be produced.

To disperse the heat from the interior of a casing, the most common way is to add a fan to carry the heat to a vent and discharge it outside the casing. Therefore, the casing comes with side walls, a top wall or a front wall with ventilation holes for inputting air. Such method can definitely achieve the effect of dispersing heat, but the convection of air may not be controlled effectively. Therefore, other methods and ways for dispersing heat are sought.

### SUMMARY OF THE INVENTION

To overcome the shortcomings of aforementioned prior art, the inventor of this invention based on years of experience of developing and selling information products to conduct researches and perform experiments and finally invented the “heat dispersing device of chassis” in accordance with this invention.

The primary objective of the present invention is to provide a heat dispersing device of a chassis comprising a hole at the bottom of a chassis and a hole on a circuit board inside the casing, such that cool air enters from the hole at the bottom of the chassis and passes through the hole on the circuit board to carry away the heat produced by the heat producing components on the circuit board.

### BRIEF DESCRIPTION OF THE DRAWINGS

The accomplishment of the above-mentioned object of the present invention will become apparent from the following description and its accompanying drawings which disclose illustrative an embodiment of the present invention, and are as follows:

FIG. 1 is a perspective view of the heat dispersing device according to a preferred embodiment of the present invention; and

FIG. 2 is a side view of the heat dispersing device according to the present invention when it is dispersing heat.

### DETAILED DESCRIPTION OF THE PREFERRED EMBODIMENTS

To make it easier for our examiner to understand the objective of the invention, its structure, innovative features, and performance, we use a preferred embodiment together with the attached drawings for the detailed description of the invention.

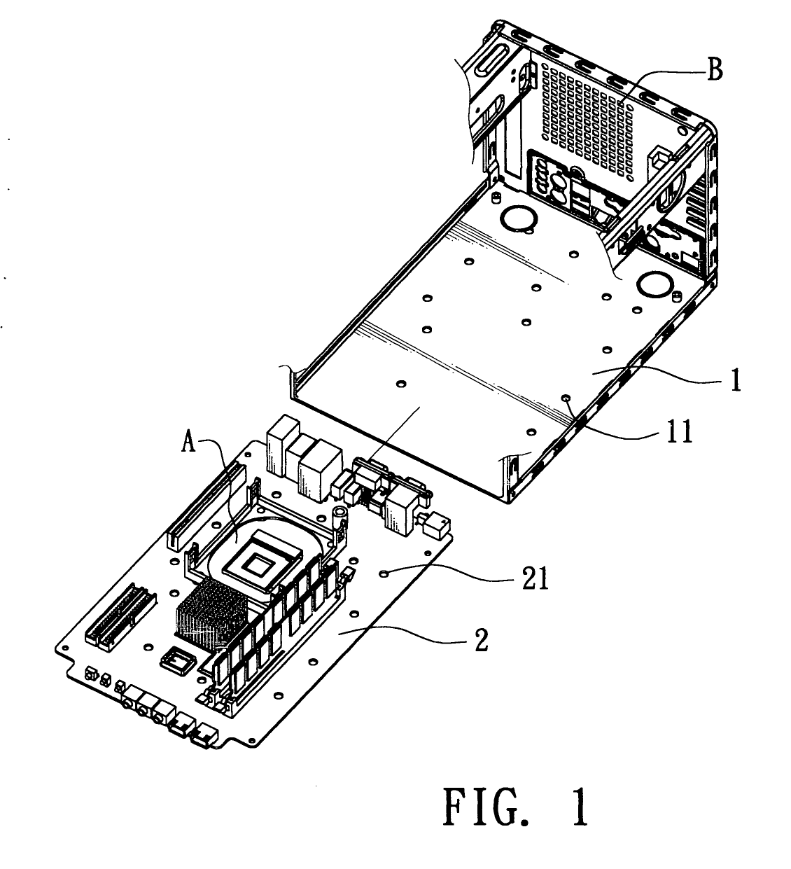

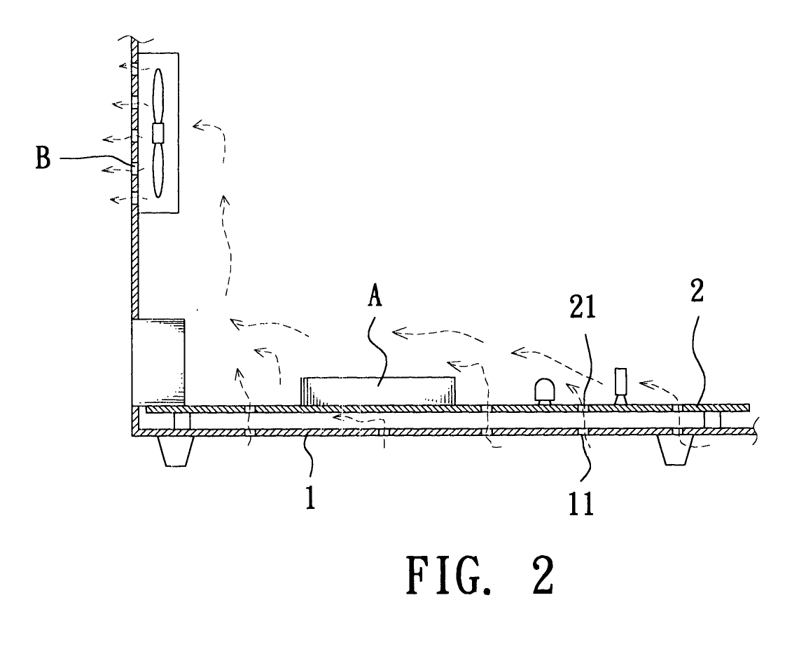

Please refer to FIGS. 1 and 2 respectively for the illustrative diagram of a preferred embodiment of this invention and the side-view diagram of the heat dispersing device according to this invention when the heat dispersing device is dispersing heat.

In the figures, the basic idea of this invention resides on using the principle of air convection to bring air with a lower temperature into a casing and force the air to flow through the heat producing components to effectively lower the temperature of the heat producing components, and then discharge the hot air outside the casing.

To achieve such objective, the heat dispersing device according to this invention comprises a chassis 1 and a circuit board 2, wherein the chassis 1 is the bottom of the casing, and a circuit board 2 is disposed and mounted onto the chassis. Unlike the prior art, the present invention has a bottom hole 11 on the chassis 1. The bottom hole 11 is in rectangular shape or comprised of a plurality of small holes, or any other hollow through apertures, and preferably located directly under a heat producing component A and away from the ventilation hole B of the casing.

The circuit board 2 is a prior-art board having electronic components thereon, and the heat producing component A may be disposed on the board. Unlike.the prior art, the present invention comprises a board hole 21 disposed at a position corresponding to the bottom hole 11 after the circuit board 2 is installed. The board hole 21 could be a rectangular groove hole or a plurality of small holes, or any other through hollow apertures, which is not limited to the position corresponding to the bottom hole 11. In other words, the board hole 21 is disposed at a corresponding position or area as shown in the preferred embodiment of this invention depicted in FIG. 2 for computer systems; however the application of this invention is not limited to this product, but also includes other electronic or electric products having heat producing components.

Please refer to FIG. 2 for a preferred embodiment of this invention. When the heat producing component A produces heat, the heat is discharged through the ventilation hole B. Since there is a bottom hole 11 and a board hole 21 in this invention, therefore the air outside the casing enters the casing through the bottom hole 11 of the chassis 1 and passes through the board hole 21 to the heat producing component A, and then the hot air is forced to discharge from the ventilation hole B. Such arrangement gives an effective heat dispersing device.

The effect accomplished by the innovative idea of this invention resides on that the cool air enters the chassis through the bottom hole 11 and the board hole 21 by means of a fan (not shown in the figure), and then the heat produced by the heat producing component A is transferred to lower the temperature of the heat producing component A. The hot air produced after the heat transfer rises, and is discharged from the ventilation hole B by means of the fan. In the meantime, the cool air enters the chassis through the bottom hole 11 and the board hole 21 again. The whole process is repeated again and again to achieve the effect of lowering the temperature.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention enhances the performance of the conventional structure, and further complies with the patent application requirements and is submitted to the Patent and Trademark Office for review and granting of the commensurate patent rights.

1. A heat dispersing device of chassis, comprising:
a bottom hole, disposed on a chassis of a casing and at a position corresponding to a circuit board inside said casing; and
a board hole, disposed on said circuit board;
such that said bottom hole and said board hole being disposed proximate a heat producing component and away from a ventilation hole.

2. The heat dispersing device of chassis of claim 1, wherein said bottom hole is one selected from the collection of an individual hole and a combination of a plurality of small holes.

3. The heat dispersing device of chassis of claim 1, wherein said bottom hole is a rectangular hollow through groove hole.

4. The heat dispersing device of chassis of claim 1, wherein said board hole is one selected from the collection of an individual hole and a combination of a plurality of small holes.

5. The heat dispersing device of chassis of claim 1, wherein said board hole is a rectangular hollow through groove hole.

6. The heat dispersing device of chassis of claim 1, wherein said casing is a computer system.

7. The heat dispersing device of chassis of claim 1, wherein said casing is a notebook computer.
